(19) United States
(12) Patent Application Publication
(10) Pub. No.: US 2011/0089967 A1
(43) Pub. Date: Apr. 21, 2011

(54) MEMS PROBE CARD AND MANUFACTURING METHOD THEREOF

(76) Inventor: Sanghee Kim, Seoul (KR)

(21) Appl. No.: 12/988,857

(22) PCT Filed: Apr. 21, 2009
(86) PCT No.: PCT/KR2009/002059

§ 371 Date: Dec. 1, 2010

(30) Foreign Application Priority Data
Apr. 21, 2008 (KR) 10-2008-0036755
Apr. 28, 2008 (KR) 10-2008-0039573
May 9, 2008 (KR) 10-2008-0043597

(51) Int. Cl. G01R 31/00; C03B 29/04; H01B 13/16; H01L 21/302

(52) U.S. Cl. 324/756.03; 156/89.12; 156/89.18; 156/89.16; 216/16; 204/192.34

(57) ABSTRACT

Provided are a micro-electro-mechanical system (MEMS) probe card and a method for manufacturing the same. The method includes preparing first to nth low-temperature co-fired ceramic (LTCC) substrates each having a via hole, filling each via hole with a via filler conductor or a resistor, stacking the first to nth LTCC substrates and firing the stacked substrates at a temperature of 1,000° C. or less to prepare a LTCC multilayer substrate, forming an insulating layer on the surface of the LTCC multilayer substrate, and forming a thin film conductive line on the surfaces of the insulating layer and the via filler conductor.

### BACKGROUND OF THE INVENTION

1. Field of the Invention

The present invention relates to a micro-electro-mechanical system (MEMS) probe card and a method for manufacturing the same, and more particularly, to a MEMS probe card and a method for manufacturing the same, in which a resistive conductive line is formed on a low-temperature co-fired ceramic (LTCC) multilayer substrate such that a stable resistance ratio can be obtained and the MEMS probe card can be stably used in the event of a significant change in power, and a ruthenium oxide (e.g., Ru₂O₃) having stable characteristics with respect to the surface of the substrate is used as the resistive conductive line so as to facilitate design of electric power distribution.

2. Description of Related Art

In general, a probe card used in a test device for electronic components such as semiconductor chips is a device including a predetermined substrate and probes arranged on the substrate. The probe card is used to test electrical characteristics of chips on a semiconductor wafer and determine whether the chips are normal or not.

The semiconductor chip includes pads on its surface to transmit and receive signals to and from an external electronic device. That is, the semiconductor chip receives an electrical signal from the external electronic device through the pads, performs a predetermined operation, and transmits the result to the external electronic device through the pads.

In this case, the probe card forms an electrical path between the semiconductor chip and the external electronic device (e.g., test device), thereby enabling an electrical test of the semiconductor chip.

Meanwhile, as semiconductor chips are becoming highly integrated, the pads of the semiconductor chip are being micronized and the distance between the pads is being reduced. Thus, it is necessary to downsize the probe card according to the high integration of semiconductor chips. However, the necessity for downsizing the probe card complicates the manufacture of the probe card.

With the upsizing of substrates and the necessity for high-speed processing due to the development of semiconductor technology, a micro-electro-mechanical system (MEMS) probe card to which a microprobe using a semiconductor MEMS technique is used is applied instead of an existing pin type probe card as the test device for semiconductor chips.

Meanwhile, a multichannel probe is required due to an increase in the number of I/O pins of the semiconductor chip. However, even when only one channel is short-circuited in the multichannel probe, an excessive current flows through the corresponding channel, which may cause a spark-induced failure at probe terminals. Thus, it is necessary to devise a plan to solve the problem.

As a part of the plan, there has recently been proposed a technique for preventing excessive current from flowing through probe terminals by connecting the probe terminals with a resistive conductive line.

FIG. 1 is a cross-sectional view showing a structure of a resistive conductive line in a conventional MEMS probe card.

As shown in FIG. 1, the conventional MEMS probe card has a structure in which a conductive line 10 is formed on the surface of a high-temperature co-fired ceramic (HTCC) substrate, a via hole formed in the conductive line 10 is filled with a via filler conductor 11, and a thin film resistor 12 and a thin film conductive line 13 for a MEMS probe are formed on the surface of the conductive line 10.

A resistive conductive line is formed by the via filler conductor 11, the thin film resistor 12, and the thin film conductive line 13, and the velocity of excessive current and the amount of current are controlled by the resistive conductive line.

Reference numeral 14 denotes a bump pad, reference numeral 15 denotes an adhesive agent, reference numeral 16 denotes a MEMS probe, and reference numeral 17 denotes a probe tip.

However, since the thin film resistor 12 is connected to the thin film conductive line 13 of the conventional MEMS probe card in series in an X or Y direction, the circuit integration is lowered, and this problem becomes more serious when the thin film resistor 12 is designed in the form of a bar.

Moreover, as shown in FIG. 1, when the thin film resistor 12 is designed to have a width equal to or smaller than that of the thin film conductive line 13, it is difficult to apply the thin film resistor 12 to the MEMS probe card which requires high electric power.

Meanwhile, the HTCC substrate is heat-treated at a temperature of 1,500° C. or more to form a multilayer wiring substrate. As insulating materials of the HTCC substrate, more than 94% alumina is used as a main material, and a small amount of silica is used as an additive. The conductive line is mainly formed of tungsten (W), which can be fired at a high temperature. Since the HTCC substrate has excellent mechanical strength and chemical resistance, it is widely applied in highly integrated packaging by forming the thin film conductive line on the surface of the HTCC substrate.

However, since the tungsten conductive line fired at a high temperature has an electrical conductivity lower than that of silver (Ag) or copper (Cu), it has inferior high frequency characteristics. Moreover, since the thermal expansion coefficient of the tungsten conductive line is more than two times as high as a silicon semiconductor device, it is a serious problem in the field of application where matching of thermal expansion coefficients is required.

Meanwhile, a low-temperature co-fired ceramic (LTCC) substrate is occasionally used instead of the HTCC substrate. In this case, the LTCC substrate is heat-treated at a temperature of 1,000° C. or less to form a multilayer wiring substrate. In manufacturing the LTCC multilayer substrate, silica, which has a low melting point, is widely used to perform the heat treatment at a low temperature of 1,000° C. or less, and a relatively small amount of alumina is used. Moreover, since the firing temperature is 1,000° C. or less in the LTCC multilayer substrate, silver (Ag) or copper (Cu) having excellent electrical conductivity is used as an electrical conductor material.

However, despite the above advantages, the LTCC multilayer substrate has a rough surface, and thus it is difficult to form a thin film resistor having a thickness of several tens to several hundreds of nanometers (nm) on the surface of the LTCC multilayer substrate.

### SUMMARY OF THE INVENTION

The present invention is directed to a MEMS probe card, which can obtain a stable resistance ratio at a high temperature and can be stably used in the event of a significant change in power, and a method for manufacturing the same.

The present invention is also directed to a MEMS probe card and a method for manufacturing the same, in which the ratio of resistance values can be easily controlled.

The present invention is also directed to a MEMS probe card and a method for manufacturing the same, in which a ruthenium oxide (e.g., Ru₂O₃) having compatibility with an LTCC multilayer substrate and an LTCC process and having stable characteristics at a high temperature is used to facilitate the design of electric power distribution.

The present invention is also directed to a MEMS probe card which can be easily manufactured and a method for manufacturing the same.

In one aspect, the present invention provides a method for manufacturing a micro-electro-mechanical system (MEMS) probe card, the method including: preparing first to nth low-temperature co-fired ceramic (LTCC) substrates each having a via hole; filling each via hole with a via filler conductor or a resistor; stacking the first to nth LTCC substrates and firing the stacked substrates at a temperature of 1,000° C. or less to prepare a LTCC multilayer substrate; forming an insulating layer on the surface of the LTCC multilayer substrate; and forming a thin film conductive line on the surfaces of the insulating layer and the via filler conductor.

The via hole of the first LTCC substrate may be filled with the via filler conductor, and the via hole of the second LTCC substrate may be filled with the resistor.

The via filler conductor and the resistor may be connected to each other by a conductive line.

The via filler conductor may include a metal selected from the group consisting of Ag, Pd, and Pt.

The resistor may include a material selected from the group consisting of ruthenium (Ru), ruthenium oxide, and Ru/ruthenium oxide.

The insulating layer may include a high-k dielectric material selected from the group consisting of Al₂O₃, HfO₂, TiO₂, ZrO₂, Y₂O₃, Ta₂O₅, and La₂O₃.

The insulating layer may be formed by a process selected from the group consisting of ion-assisted physical vapor deposition (PVD) having a high film deposition rate, PVD as e-beam evaporation, pulsed laser deposition (PLD), and aerosol deposition.

The thin film conductive line may include a mixed metal of Ti, Pd, Cu, or Al, Cu, Au.

The insulating layer and the thin film conductive line may be formed by a wet etching process or an ion milling process.

In another aspect, the present invention provides a micro-electro-mechanical system (MEMS) probe card including: a low-temperature co-fired ceramic (LTCC) multilayer substrate prepared by stacking first to nth LTCC substrates, each having a via hole filled with a via filler conductor or a resistor, and firing the stacked substrates at a temperature of 1,000° C. or less; an insulating layer formed on a surface of the LTCC multilayer substrate; and a thin film conductive line formed on the surfaces of the insulating layer and the via filler conductor.

In still another aspect, the present invention provides a method for manufacturing a micro-electro-mechanical system (MEMS) probe card, the method including: preparing a low-temperature co-fired ceramic (LTCC) substrate fired at a temperature of 1,000° C. or less; forming a thick film resistive layer on the LTCC substrate; forming an insulating layer on the thick film resistive layer; and forming a thin film conductive line on the insulating layer and the thick film resistive layer.

The thick film resistive layer may be formed on a via filler conductor disposed on the LTCC substrate.

The thick film resistive layer may be formed on a conductive line disposed on the LTCC substrate.

In forming the thick film resistive layer, the thick film resistive layer may be formed by printing and then fired.

The method may further include heat-treating the LTCC substrate before forming the thick film resistive layer.

The insulating layer may include a high-k dielectric material selected from the group consisting of Al₂O₃, HfO₂, TiO₂, ZrO₂, Y₂O₃, Ta₂O₅, and La₂O₃.

The insulating layer may be formed by a process selected from the group consisting of ion-assisted physical vapor deposition (PVD) having a high film deposition rate, PVD as e-beam evaporation, pulsed laser deposition (PLD), and aerosol deposition.

The thick film resistive layer may include Ru₂O₃.

The thin film conductive line may include a mixed metal of Ti, Pd, Cu, or Al, Cu, Au.

The thick film resistive layer, the insulating layer, and the thin film conductive line may be formed by a wet etching process or an ion milling process.

In yet another aspect, the present invention provides a micro-electro-mechanical system (MEMS) probe card including: a thick film resistive layer formed on a low-temperature co-fired ceramic (LTCC) substrate fired at a temperature of 1,000° C. or less; an insulating layer formed on the thick film resistive layer; and a thin film conductive line formed on the insulating layer and the thick film resistive layer.

In yet another aspect, the present invention provides a method for manufacturing a micro-electro-mechanical system (MEMS) probe card, the method including: forming a first conductive pad on a surface of a substrate; forming a resistor on the surfaces of the substrate and the first conductive pad; and forming a second conductive pad on the surfaces of the substrate and the resistor.

In yet another aspect, the present invention provide a micro-electro-mechanical system (MEMS) probe card including: a first conductive pad formed on a surface of a substrate; a resistor formed on the surfaces of the substrate and the first conductive pad; and a second conductive pad formed on the surfaces of the substrate and the resistor.

### BRIEF DESCRIPTION OF THE DRAWINGS

FIG. 1 is a cross-sectional view showing a structure of a conventional MEMS probe card;

FIG. 2 is a diagram illustrating a method for manufacturing a MEMS probe card in accordance with a first exemplary embodiment of the present invention;

FIGS. 3 to 10 are diagrams illustrating the individual processes shown in FIG. 2;

FIG. 11 is a diagram illustrating a method for manufacturing a MEMS probe card in accordance with a second exemplary embodiment of the present invention;

FIGS. 12 to 21 are diagrams illustrating the individual processes shown in FIG. 11; and

FIG. 22 is a diagram showing a probe card in accordance with another exemplary embodiment of the present invention.

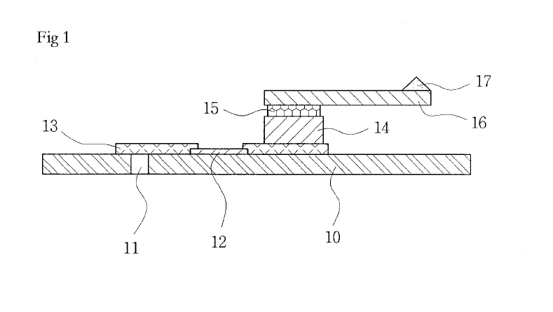

### DETAILED DESCRIPTION OF THE INVENTION

Hereinafter, exemplary embodiments of the present invention will be described in detail with reference to the accompanying drawings.

### First Exemplary Embodiment

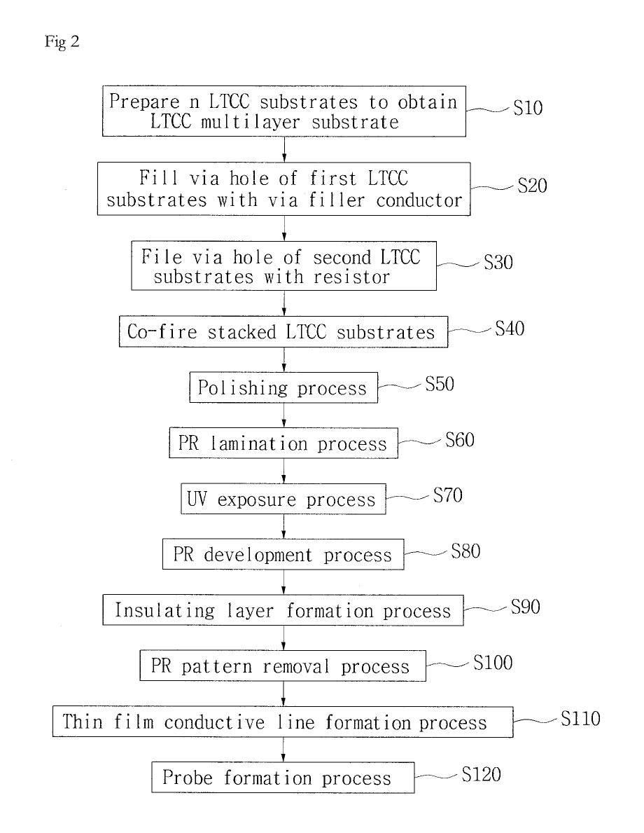

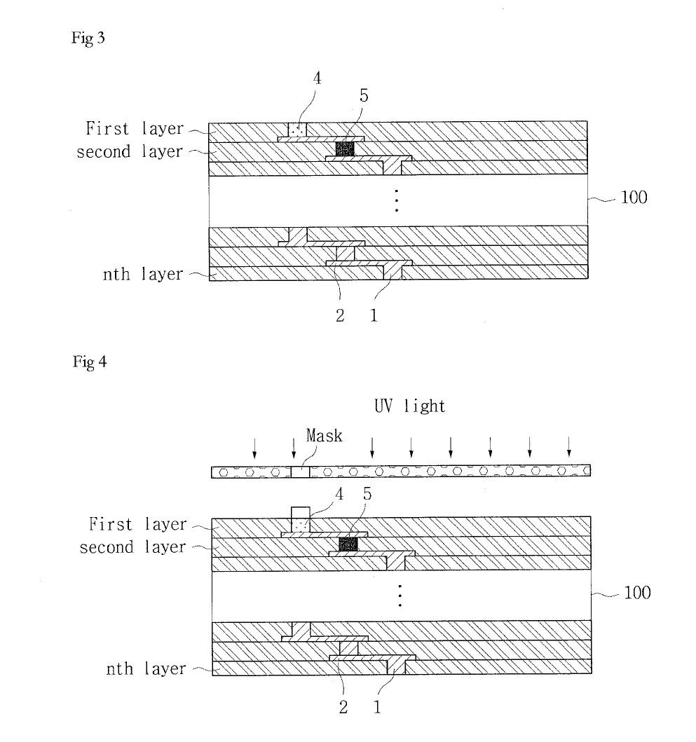

FIG. 2 is a diagram illustrating a method for manufacturing a MEMS probe card in accordance with a first exemplary embodiment of the present invention, and FIGS. 3 to 10 are diagrams illustrating the individual processes shown in FIG. 2.

As shown in FIGS. 2 and 3, in this exemplary embodiment of the present invention, n LTCC substrates are prepared to obtain an LTCC multilayer substrate 100 (S10). The number of layers of the LTCC multilayer substrate 100 may vary according to the substrate design and is preferably 20 to 30 layers according to the test conditions of semiconductor chips. Here, silver (Ag) is mainly used as a material for a metal wiring, and the composition may vary, if necessary. Moreover, ceramic materials used in the LTCC substrate include more than 60 to 70% glass and the remaining alumina. The thickness of each LTCC substrate may vary according to requirements of customers, and is preferably 4 to 7 mm.

Meanwhile, a via hole 1 penetrates each LTCC substrate, and a conductive line 2 is formed on the front or rear surface of each LTCC substrate.

The via hole 1 formed in the first LTCC substrate is filled with a via filler conductor 4 (S20), and the via hole 1 formed in the second LTCC substrate is filled with a resistor 5 (S30). The via filler conductor 4 and the resistor 5 are connected to each other by the conductive line 2.

The via filler conductor 4 may be formed of a metal selected from the group consisting of silver (Ag), palladium (Pd), and platinum (Pt), and preferably Pd or Pt in view of conductivity. Although the description has been made with respect to the structure in which only the first LTCC substrate is filled with the via filler conductor 4 as shown in FIG. 3, the present invention is not limited thereto, and the third or fourth LTCC substrate may be filled with the via filler conductor 4.

The resistor 5 is formed of a material selected from the group consisting of ruthenium (Ru), a ruthenium oxide (e.g., RuO₂, Ru₂O₃, etc.), and Ru/ruthenium oxide. The via hole 1 is filled with the resistor 5 by chemical vapor deposition (CVD) or atomic layer deposition (ALD).

Next, the first to nth LTCC substrates are stacked and co-fired at a temperature of 1,000° C. or less, preferably at a temperature of about 850 to 900° C., to produce an LTCC multilayer substrate 100 (S40).

The surface of the fired LTCC multilayer substrate 100 is rough since the glass and alumina components are bonded to each other, and thus a polishing process is performed (S50).

That is, to form a thin film pattern on the surface of the LTCC multilayer substrate 100, it is required that the surface of the LTCC substrate have a roughness of 1 μm or less, and thus the polishing process is performed on the surface of the LTCC substrate. In this case, it is preferable that the LTCC substrate be formed to a thickness greater than a polishing thickness in view of substrate warpage and that the polishing process be subsequently performed. Generally, the polishing thickness is about 50 to 100 μM, and the surface of the substrate is subjected to heat treatment.

To form an insulating layer on the surface of the first substrate of the LTCC multilayer substrate 100 shown in FIG. 3 using a high-k dielectric material selected from the group consisting of Al₂O₃, HfO₂, TiO₂, ZrO₂, Y₂O₃, Ta₂O₅, and La₂O₃, the surface of the first substrate is washed, and then a process of laminating dry photoresist (PR) thickly on the surface of the substrate using a laminator is performed (S60). Here, the pressure, temperature, and speed of the laminator may be properly controlled to prevent the formation of pores. If pores are formed in the photoresist, the laminating process may be repeated. It is important that the photoresist has a large thickness, if possible, and preferably a thickness of 120 or more.

After completion of the PR lamination process, a UV exposure process is performed (S70), in which UV light is irradiated on the photoresist to form a pattern (see FIGS. 2 and 4). In this case, a mask pattern is designed so that the irradiated portion is polymerized, and the photoresist is exposed to UV light using a dual exposure system, for example. Here, the important factors are the power of a UV light source and the exposure time. If the power of the UV light source is strong and the exposure time is long, the photoresist is underdeveloped, and thus a pattern larger than a desired pattern is formed. Whereas, if the power of the UV light source is weak and the exposure time is short, the photoresist is overdeveloped and thus a pattern smaller than the desired pattern is formed.

After completion of the UV exposure process, a PR development process is performed (S80), in which a PR pattern 6 is formed on the via filler conductor 4 (see FIGS. 2 and 5). Meanwhile, it is possible to obtain a more accurate pattern for a shorter time by spraying a developing solution on the LTCC substrate through a spray nozzle. Here, the important factors are the concentration and temperature of the developing solution, the pressure of the spray nozzle, and the speed of a conveyor belt. If the factors such as the concentration, temperature, pressure, and speed of the solution are not properly controlled, it is difficult to obtain an accurate pattern.

Meanwhile, when photoresist scum remains on the surface of the developed LTCC multilayer substrate 100, i.e., the surface of the first LTCC substrate, the insulating layer is not well formed on the surface of the LTCC substrate, and thus a descum process using O₂ plasma is performed in a vacuum state using a plasma device to remove a small amount of photoresist scum remaining on the surface of the LTCC substrate. The descum process is a process of removing the small amount of photoresist scum remaining after the PR development process in a dry manner.

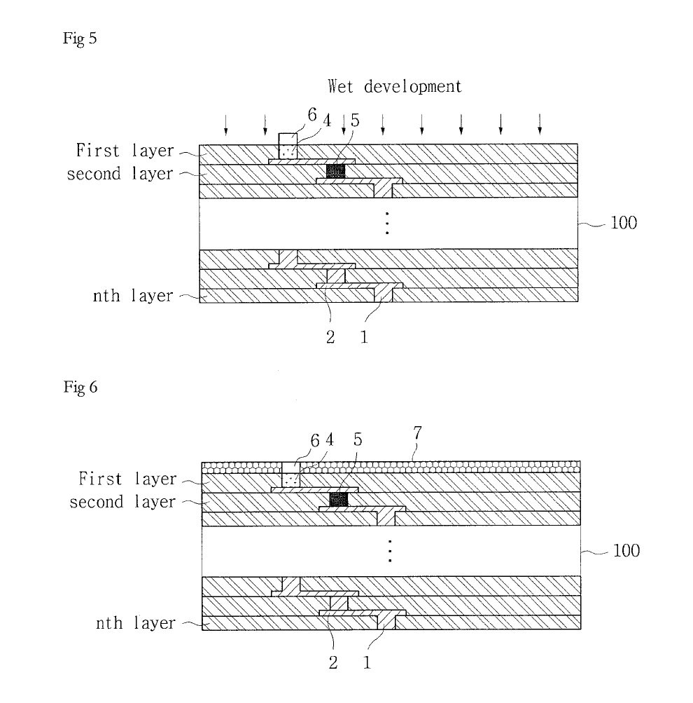

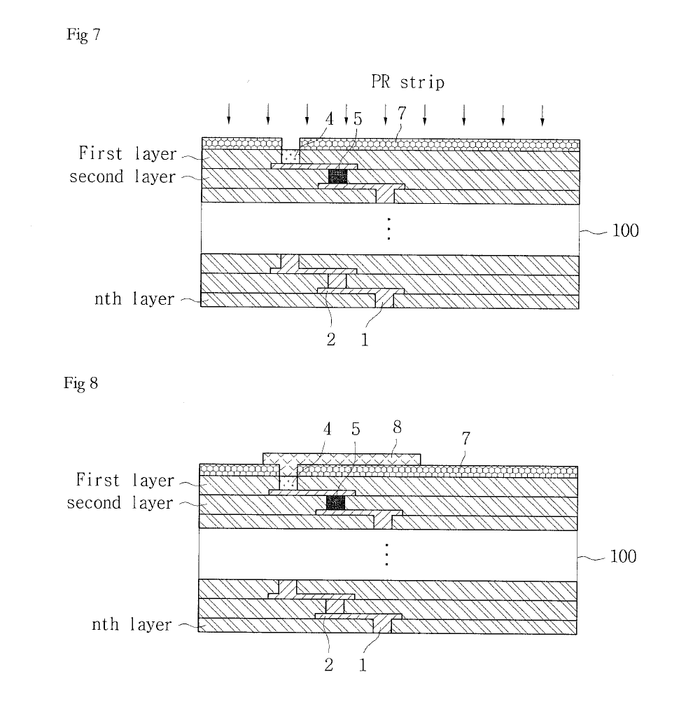

Next, a process of forming an insulating layer 7 on the LTCC multilayer substrate 100 is performed (S90) (see FIGS. 2 and 6). Since the LTCC multilayer substrate 100 contains a large amount of voids and the surface of substrate is formed of glass, it has inferior chemical resistance. To make up for this drawback, a layer having excellent insulating properties is formed on the surface of the LTCC multilayer substrate 100. In the present invention, an Al₂O₃ layer, a stabilized ZrO₂, or a TiO₂ layer is formed to a thickness of 5 to 10 μm by ion-assisted physical vapor deposition (PVD) having a high film deposition rate, PVD as e-beam evaporation, pulsed laser deposition (PLD), or aerosol deposition. The temperature of the LTCC multilayer substrate 100 is room temperature, and the amount of carrier gas (He or O₂), the pressure in a vacuum chamber, and the structure and shape of a nozzle are properly controlled to increase the density of the insulating layer 7. Then, a process of removing the PR pattern 6 and a part of the insulating layer 7 formed on the PR pattern 6 is performed (S100) to open the via filler conductor 4 (see FIGS. 2 and 7). This process is performed using a PR strip apparatus, for example. During the PR strip, when the concentration of a stripper solution and the nozzle pressure are properly controlled and ultrasonic waves are applied simultaneously, it is possible to easily remove the photoresist. Here, it is important to control the ultrasonic power.

After completion of the PR pattern removal process, a process of depositing a thin film conductive line 8 on the via filler conductor 4 and the insulating layer 7 is performed (S110) (see FIGS. 2 and 8). Here, a Ti or Al layer having a high adhesion strength is deposited to a thickness of 2,000 to 5,000 Å, preferably 3,000 Å, by sputtering to improve the adhesion properties of the thin film conductive line 8 to the insulating layer 7 and the via filler conductor 4. Then, a palladium (Pd) layer, which serves as a barrier between the Ti or Al layer and a copper (Cu) layer, is deposited to a thickness of 50 to 200 Å, preferably 70 Å on the Ti or Al layer. Finally, a Cu layer, a main conductive line, is deposited to a thickness of 2,500 to 10,000 Å, preferably 9,000 Å or more, on the Pd layer, thereby forming a base metal layer.

Meanwhile, it is preferable that the thin film conductive line 8 includes a mixed metal of Ti, Pd, Cu and Au, or Al, Cu, Ni and Au. Here, the Ni is used to prevent interdiffusion between the Cu layer and the Au layer, and if the Au layer has a thickness of 5 μm or more, preferably 5 to 10 μm, the Ni may be eliminated.

Moreover, in the processes of forming the insulating layer 7 and the thin film conductive line 8, a wet etching process using a chemical solution or a dry etching process using an ion milling apparatus and Ar, Xe, or other reactant gases may be employed.

In the wet etching process, a metal etching solution is sprayed onto the surface of the LTCC substrate, and the resulting substrate is washed with deionized (D.I) water and then dried.

An undercut phenomenon occurs in the wet etching process. Thus, if an ion milling process capable of reducing the undercut phenomenon is employed, it is possible to form a high precision microstrip line. The ion milling process, a dry etching process, has a drawback in that the apparatus is expensive; however, it is an indispensable processing technique in the fabrication of precise parts.

A resistive conductive line for a MEMS probe card in accordance with the present invention is completed by the conductive line 2, the via filler conductor 4, the resistor 5, the insulating layer 7, and the thin film conductive line 8.

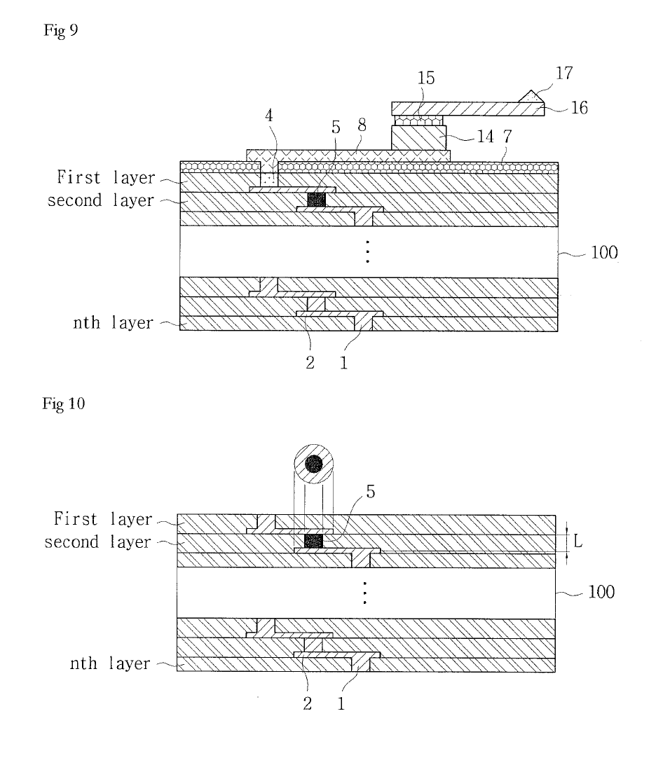

Then, as shown in FIG. 9, a bump pad 14 is formed on the thin film conductive line 8, and a MEMS probe 16 and a probe tip 17 are sequentially fixed on the bump pad 14 using an adhesive 15, thereby completing a MEMS probe card in accordance with the present invention (S120).

Meanwhile, as shown in FIG. 10, the height and diameter of the resistor 5 formed in the via hole of the second LTCC substrate may be increased according to the thickness of the second LTCC substrate or the diameter of the via hole, and thus it is possible to design the resistor 5 to have various resistance values for a variety of uses.

### Second Exemplary Embodiment

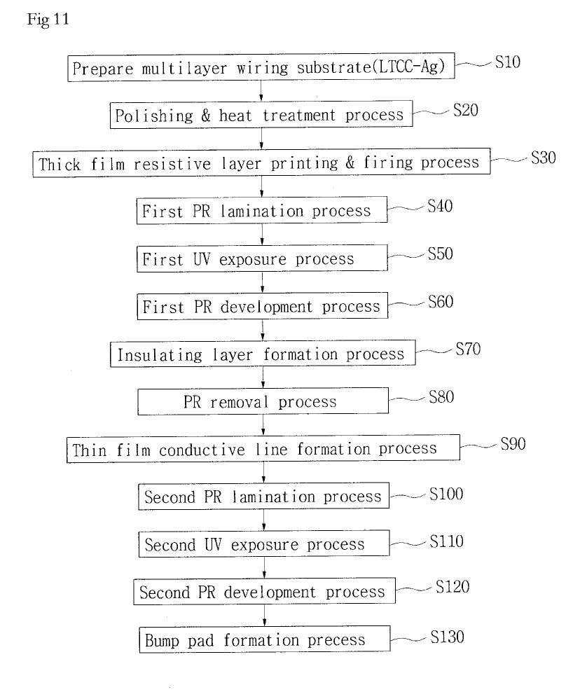

FIG. 11 is a diagram illustrating a method for manufacturing a MEMS probe card in accordance with a second exemplary embodiment of the present invention, and FIGS. 12 to 21 are diagrams illustrating the individual processes shown in FIG. 11.

As shown in FIG. 12, in this exemplary embodiment, an LTCC multilayer substrate 100 including n LTCC substrates are prepared (S10). The number of layers of the LTCC multilayer substrate may vary according to the substrate design and is preferably 20 to 30 layers. Here, silver (Ag) is mainly used as a material for a metal wiring, and the composition may vary, if necessary. Ceramic materials used in the LTCC substrate include more than 60 to 70% glass and the remaining alumina. The thickness of each LTCC substrate may vary according to requirements of customers, and is preferably 4 to 7 mm. In FIG. 12, reference numeral 1 denotes a via hole (through hole) formed in the substrate, and reference numeral 2 denotes a conductive line formed in the substrate.

The LTCC multilayer substrate 100 is manufactured by printing a wiring on each of n green sheets, stacking all the layers, and co-firing the stacked layers at a temperature of 1,000° C. or less, preferably at a temperature of about 850 to 900° C. Since the glass and alumina components are bonded to each other on the substrate surface, the surface is rough. To form a thin film pattern, it is required that the substrate surface has a roughness of 1 μm or less, and thus a mechanical polishing process is performed. During design of the substrate, it is preferable that the substrate be formed to a thickness greater than a polishing thickness in view of substrate warpage and that the polishing process be subsequently performed. Generally, the polishing thickness is about 50 to 100 μm, and the substrate surface is subjected to heat treatment annealing (S20).

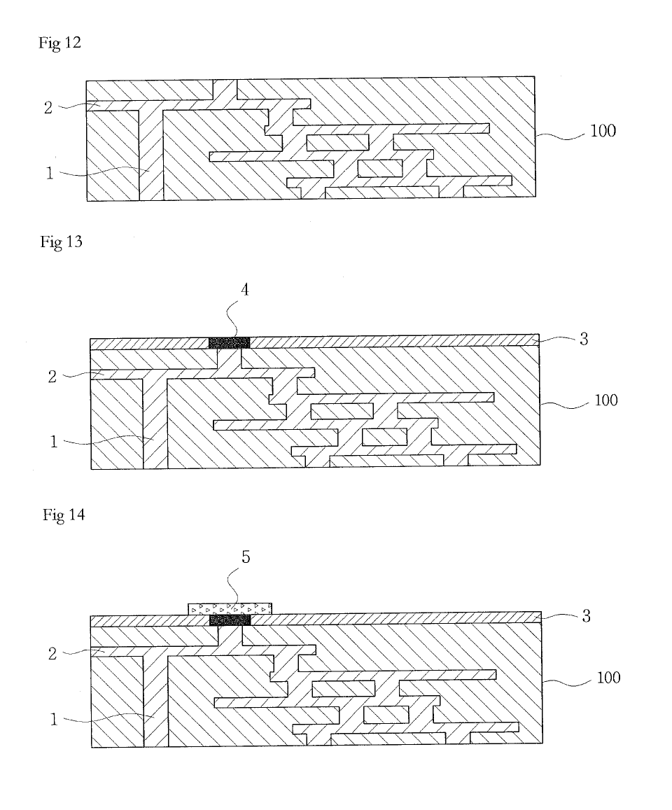

Next, as shown in FIG. 13, a conductive line 3 and a via filler conductor 4 are formed on the LTCC multilayer substrate 100, and as shown in FIG. 14, Ru₂O₃, which has stable characteristics is formed as a thick film resistive layer 5.

The thick film resistive layer 5 is formed by printing and then fired (S30).

Then, to form an insulating layer on the conductive line 3 and the thick film resistive layer 5 using a high-k dielectric material selected from the group consisting of Al₂O₃, HfO₂, TiO₂, ZrO₂, Y₂O₃, Ta₂O₅, and La₂O₃, the surface is washed, and then a first PR lamination process of laminating dry photoresist (PR) thickly on the surface of the substrate using a laminator is performed (S40). Here, the pressure, temperature, and speed of the laminator may be properly controlled to prevent the formation of pores. If pores are formed in the photoresist, the laminating process may be repeated. It is important that the photoresist have a large thickness, if possible, and preferably a thickness of 120 μm or more.

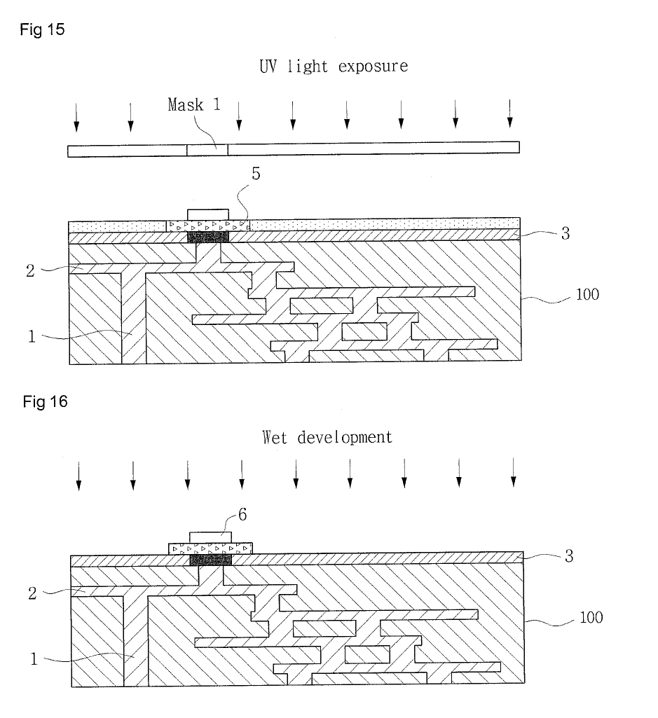

The process shown in FIG. 15 is a first UV exposure process (S50), in which a pattern is formed by irradiating light onto the photoresist. A pattern of Mask 1 is designed so that the irradiated portion is polymerized, and the photoresist is exposed to UV light using a dual exposure system, for example. Here, the important factors are the power of a UV light source and the exposure time. If the power of the UV light source is strong and the exposure time is long, the photoresist is underdeveloped, and thus a pattern larger than a desired pattern is formed. Whereas, if the power of the UV light source is weak and the exposure time is short, the photoresist is overdeveloped, and thus a pattern smaller than the desired pattern is formed.

The process shown in FIG. 16 is a first PR development process (S60), in which a photoresist (PR) pattern 6 is formed on a part of the surface of the thick film resistive layer 5. It is possible to obtain a more accurate PR pattern 6 for a shorter time by spraying a developing solution on the substrate through a spray nozzle. Here, the important factors are the concentration and temperature of the developing solution, the pressure of the spray nozzle, and the speed of a conveyor belt. If the factors such as the concentration, temperature, pressure, and speed of the solution are not properly controlled, it is difficult to obtain an accurate pattern.

When photoresist scum remains on the surface of the developed substrate, the insulating layer is not well formed on the substrate surface, and thus a descumming process using O₂ plasma is performed in a vacuum state using a plasma device to remove a small amount of photoresist scum remaining on the substrate surface. The descumming process is a process of removing the small amount of photoresist scum remaining after the PR development process in a dry manner.

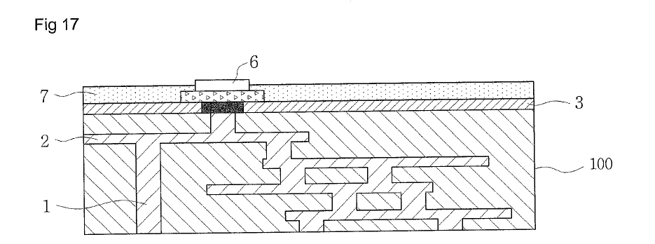

Next, a process of forming an insulating layer 7 on the LTCC multilayer substrate 100 is performed (S70) as shown in FIG. 17. Since the LTCC multilayer substrate 100 contains a large amount of voids and the substrate surface is formed of glass, it has inferior chemical resistance. To make up for this drawback, an alumina-stabilized zirconia layer having excellent insulating properties is formed on the surface of the LTCC multilayer substrate 100. In the present invention, an Al₂O₃ layer, a stabilized ZrO₂, or a TiO₂ layer is formed to a thickness of 5 to 10 μm by ion-assisted physical vapor deposition (PVD) having a high film deposition rate, PVD as e-beam evaporation, pulsed laser deposition (PLD), or aerosol deposition. Preferably, the aerosol deposition is employed. At this time, the temperature of the substrate is room temperature, and the amount of carrier gas (He or O₂), the pressure in a vacuum chamber, and the structure and shape of a nozzle are properly controlled to increase the density of the insulating layer 7.

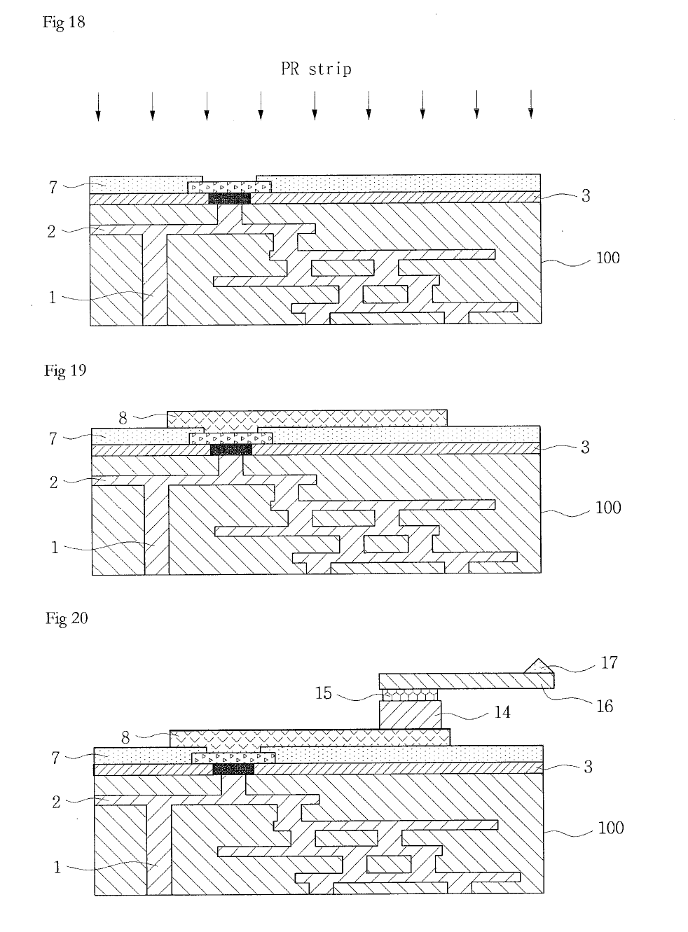

The process shown in FIG. 18 is a process of removing the insulating layer 7 on the PR pattern 6 and the photoresist (S80) to open the thick film resistive layer 5. A part of the insulating layer 7 is removed by mechanical scrubbing and then using a PR strip apparatus. During the PR strip, when the concentration of a stripper solution and the nozzle pressure are properly controlled and ultrasonic waves are applied simultaneously, it is possible to easily remove the photoresist. Here, it is important to control the ultrasonic power.

The process shown in FIG. 19 is a process of depositing a thin film conductive line 8 on the thick film resistive layer 5 and the insulating layer 7 (S90). In order to improve the adhesion properties of the thin film conductive line 8 to the insulating layer 7 and the thick film resistive layer 5, a Ti or Al layer having a high adhesion strength is deposited to a thickness of 2,000 to 5,000 Å, preferably 3,000 Å, by sputtering. Then, a palladium (Pd) layer, which serves as a barrier between the Ti or Al layer and a copper (Cu) layer, is deposited to a thickness of 50 to 200 Å, preferably 70 Å, on the Ti or Al layer. Finally, a Cu layer, a main conductive line, is deposited to a thickness of 2,500 to 10,000 Å, preferably 9,000 Å or more on the Pd layer, thereby forming a base metal layer.

Then, a second PR lamination process of laminating photoresist for forming the thin film conductive line 8 on both surfaces of the substrate is performed (S100). The photoresist used in this process may be the same as or different from the photoresist used in the first PR lamination process according to the type of pattern and operation conditions.

Next, a second UV exposure process is performed (S110), in which dry negative photoresist is used and thus a pattern of Mask 2 different from that of Mask 1 is used. The operation factors are the same as the first UV exposure process; however, the operation conditions have different values according to the thickness of the photoresist.

Subsequently, a second PR development process is performed on the photoresist (S120), in which the same developing apparatus may be used and the operation conditions are different from those of the first UV exposure process.

If necessary, photoresist scum remaining on the surface of the developed substrate is removed by a descum process using O₂ plasma. The thin film conductive line 8 as shown in FIG. 19 is formed by the above-described processes.

Moreover, the process of forming the thin film conductive line 8 is a plating process of depositing a thick metal layer to thicken the metal wiring layer, thereby increasing the electrical conductivity of the thin film wiring and reducing the electrical resistance of the high frequency line. In this case, the thin film conductive line 8 includes a mixed metal of Ti, Pd, Cu and Au, or Al, Cu, Ni and Au. A Cu layer, a main conductive line, is deposited to a thickness of 10 to 25 μm, a Ni layer is deposited to a thickness of 2 to 4 μm, and an Au layer is deposited to a thickness of less than 5 μm. The thickness of the metal layers may vary according to the types of products to be used. Here, the Ni may be selectively eliminated. The reason for this is that the Ni is used to prevent interdiffusion between the Cu layer and the Au layer, and if the Au layer has a thickness of 5 μm or more, preferably 5 to 10 μm, the Ni may be eliminated.

As such, a MEMS probe card in accordance with the present invention is completed by the via filler conductor 4, the thick film resistive layer 5, the insulating layer 7, and the thin film conductive line 8.

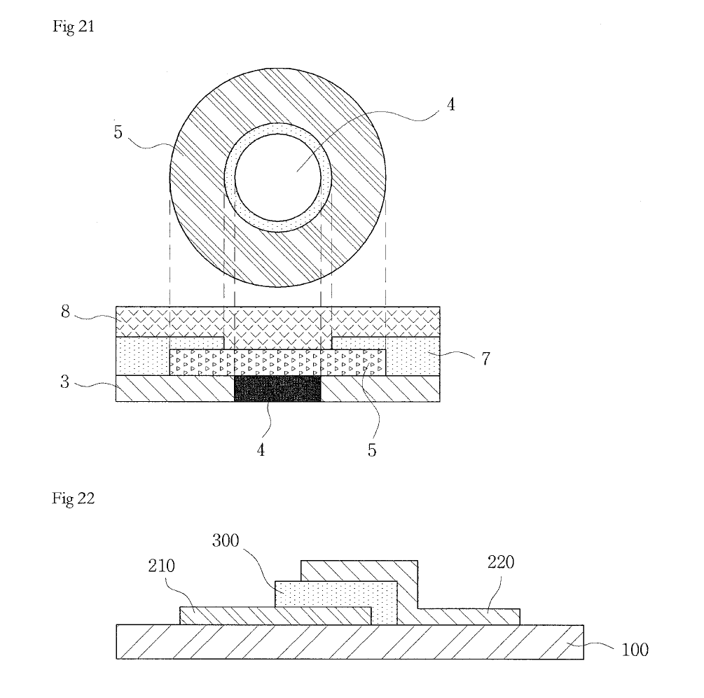

Then, as shown in FIGS. 20 and 21, a bump pad 14 is formed on the thin film conductive line 8, and a MEMS probe 16 and a probe tip 17 are sequentially fixed on the bump pad 14 using an adhesive 15, thereby completing a MEMS probe card used in a test device for electronic components in accordance with the present invention (S130).

Moreover, in the processes of forming the thick film resistive layer 5, the insulating layer 7, and the thin film conductive line 8, a wet etching process using a chemical solution or a dry etching process using an ion milling apparatus and Ar, Xe, or other reactant gases may be employed.

In the wet etching process, a metal etching solution is sprayed onto both surfaces of the substrate, and the resulting substrate is washed with deionized (D.I) water and then dried.

An undercut phenomenon occurs in the wet etching process. Thus, if an ion milling process capable of reducing the undercut phenomenon is employed, it is possible to form a high precision microstrip line. The ion milling process, a dry etching process, has a drawback in that the apparatus is expensive; however, it is an indispensable processing technique in the fabrication of precise parts.

### Another Exemplary Embodiment

As shown in FIG. 22, a probe card in accordance with another exemplary embodiment of the present invention includes a first conductive pad 210 formed on the surface of a substrate 100, a resistor 300 formed on the surfaces of the substrate 100 and the first conductive pad 210, and a second conductive pad 220 formed on the surfaces of the substrate 100 and the resistor 300.

That is, the probe card has a sandwich resistor in which the resistor 300 is interposed between the first conductive pad 210 and the second conductive pad 220.

With this configuration, the resistance has a value of an integer multiple of the sheet resistance. Compared to a bar type resistor, (1) it is possible to reduce the area of the conductive pad or eliminate the conductive pad since a resistor and an electrode are formed on the same surface, thereby enabling high density circuit design, and (2) it is possible to design a conductive line having a stacked structure without a separate conductive line when the resistor is connected with a plurality of conductive lines.

Moreover, according to the present invention, it is possible to effectively design a resistor of several ohms or less, and an existing protective layer is not required due to the protection of its surface. Further, it is possible to save raw materials, thereby enabling environmentally-friendly circuit design.

Also, the above configuration may be reflected in the design of the thin film and thick film resistors and enable high density circuit design. And, it is possible to form the resistor on a capacitor.

Next, a method for forming the probe card shown in FIG. 22 will be described.

First, a first conductive pad 210 is formed on the surface of a substrate 100.

Then, a resistor 300 is formed on the surfaces of the substrate 100 and the first conductive pad 210.

Next, a second conductive pad 220 is formed on the surfaces of the substrate 100 and the resistor 300.

The first conductive pad 210 formed by first printing is a first conductor including an AG paste containing small amounts of Ag, Pd, Pt, and Ti.

A screen printing process may be employed as the printing process.

The resistor 300 formed by second printing may include Ru₂O₃ and have a resistance of 10 KΩ to 10 MΩ. In the present invention, a resistor of 3 to 8 MΩ is used.

The printing process is carried out 3 to 7 times, which may vary according to the resistance value required.

The heat treatment temperature is in the range of about 500 to 900° C.

The second conductive pad 220 is formed by third printing under the same conditions as the first printing.

As described above, according to a MEMS probe card and a method for manufacturing the same, since a via hole is filled with a resistor, a stable resistance value can be obtained, the ratio of the resistance values can be easily controlled, and the MEMS probe card can be stably used in the event of a significant change in power during the test of semiconductor chips.

Moreover, according to the MEMS probe card and the method for manufacturing the same, it is possible to employ an existing process of manufacturing a LTCC multilayer substrate without a pattern for forming a resistive conductive line and any additional process.

Furthermore, according to the MEMS probe card and the method for manufacturing the same, it is possible to facilitate the design of electric power distribution in a test device for electronic components.

In addition, according to the MEMS probe card and the method for manufacturing the same, it is possible to allow the LTCC multilayer substrate to have stable characteristics at a high temperature.

While exemplary embodiments of the present invention have been described and illustrated, it should be understood that various modifications to the described embodiments, which may be evident to those skilled in the art, can be made without departing from the spirit and scope of the present invention as defined by the appended claims.

What is claimed is:

1. A method for manufacturing a micro-electro-mechanical system (MEMS) probe card, the method comprising:
preparing first to nth low-temperature co-fired ceramic (LTCC) substrates each having a via hole;
filling each via hole with a via filler conductor or a resistor;
stacking the first to nth LTCC substrates and firing the stacked substrates at a temperature of 1,000° C. or less to prepare a LTCC multilayer substrate;
forming an insulating layer on a surface of the LTCC multilayer substrate; and
forming a thin film conductive line on the surfaces of the insulating layer and the via filler conductor.

2. The method of claim 1, wherein the via hole of the first LTCC substrate is filled with the via filler conductor, and the via hole of the second LTCC substrate is filled with the resistor.

3. The method of claim 1, wherein the via filler conductor and the resistor are connected to each other by a conductive line.

4. The method of claim 3, wherein the via filler conductor is formed of a metal selected from the group consisting of Ag, Pd, and Pt.

5. The method of claim 3, wherein the resistor is formed of a material selected from the group consisting of ruthenium (Ru), ruthenium oxide, and Ru/ruthenium oxide.

6. The method of claim 5, wherein the height and diameter of the via hole of the second substrate including the resistor vary.

7. The method of claim 1, wherein the insulating layer is formed of a high-k dielectric material selected from the group consisting of Al₂O₃, HfO₂, TiO₂, ZrO₂, Y₂O₃, Ta₂O₅, and La₂O₃.

8. The method of claim 7, wherein the insulating layer is formed by a process selected from the group consisting of ion-assisted physical vapor deposition (PVD) having a high film deposition rate, PVD as e-beam evaporation, pulsed laser deposition (PLD), and aerosol deposition.

9. The method of claim 1, wherein the thin film conductive line comprises a mixed metal of Ti, Pd, Cu, or Al, Cu, Au.

10. The method of claim 9, wherein the insulating layer and the thin film conductive line are formed by a wet etching process or an ion milling process.

11. A micro-electro-mechanical system (MEMS) probe card comprising:
a low-temperature co-fired ceramic (LTCC) multilayer substrate prepared by stacking first to nth LTCC substrates, each having a via hole filled with a via filler conductor or a resistor, and firing the stacked substrates at a temperature of 1,000° C. or less;
an insulating layer formed on a surface of the LTCC multilayer substrate; and
a thin film conductive line formed on the surfaces of the insulating layer and the via filler conductor.

12. The MEMS probe card of claim 11, wherein the via hole of the first LTCC substrate is filled with the via filler conductor, and the via hole of the second LTCC substrate is filled with the resistor.

13. The MEMS probe card of claim 11, further comprising a conductive line connecting the via filler conductor and the resistor.

14. A method for manufacturing a micro-electro-mechanical system (MEMS) probe card, the method comprising:
preparing a low-temperature co-fired ceramic (LTCC) substrate fired at a temperature of 1,000° C. or less;
forming a thick film resistive layer on the LTCC substrate;
forming an insulating layer on the thick film resistive layer; and
forming a thin film conductive line on the insulating layer and the thick film resistive layer.

15. The method of claim 14, wherein the thick film resistive layer is formed on a via filler conductor disposed on the LTCC substrate.

16. The method of claim 15, wherein the thick film resistive layer is formed on a conductive line disposed on the LTCC substrate.

17. The method of claim 14, wherein in forming the thick film resistive layer, the thick film resistive layer is formed by printing and then fired.

18. The method of claim 14, further comprising heat-treating the LTCC substrate before forming the thick film resistive layer.

19. The method of claim 14, wherein the insulating layer is formed of a high-k dielectric material selected from the group consisting of Al₂O₃, HfO₂, TiO₂, ZrO₂, Y₂O₃, Ta₂O₅, and La₂O₃.

20. The method of claim 19, wherein the insulating layer is formed by a process selected from the group consisting of ion-assisted physical vapor deposition (PVD) having a high film deposition rate, PVD as e-beam evaporation, pulsed laser deposition (PLD), and aerosol deposition.

21. The method of claim 14, wherein the thick film resistive layer is formed of Ru₂O₃.

22. The method of claim 14, wherein the thin film conductive line comprises a mixed metal of Ti, Pd, Cu, or Al, Cu, Au.

23. The method of claim 14, wherein the thick film resistive layer, the insulating layer, and the thin film conductive line are formed by a wet etching process or an ion milling process.

24. A micro-electro-mechanical system (MEMS) probe card comprising:
a thick film resistive layer formed on a low-temperature co-fired ceramic (LTCC) substrate fired at a temperature of 1,000° C. or less;
an insulating layer formed on the thick film resistive layer; and
a thin film conductive line formed on the insulating layer and the thick film resistive layer.

25. The MEMS probe card of claim 24, wherein the thick film resistive layer comprises a via filler conductor disposed on the LTCC substrate, and the thick film resistive layer is formed on the via filler conductor.

26. The MEMS probe card of claim 24, wherein the thick film resistive layer is formed on a conductive line disposed on the LTCC substrate.

27. The MEMS probe card of claim 24, wherein the thick film resistive layer is formed by printing and then fired.

28. The MEMS probe card of claim 24, wherein the insulating layer is formed of a high-k dielectric material selected from the group consisting of Al₂O₃, HfO₂, TiO₂, ZrO₂, Y₂O₃, Ta₂O₅, and La₂O₃.

29. The MEMS probe card of claim 28, wherein the insulating layer is formed by a process selected from the group consisting of ion-assisted physical vapor deposition (PVD) having a high film deposition rate, PVD as e-beam evaporation, pulsed laser deposition (PLD), and aerosol deposition.

30. The MEMS probe card of claim 24, wherein the thick film resistive layer is formed of Ru₂O₃.

31. The MEMS probe card of claim 24, wherein the thin film conductive line is formed of a mixed metal of Ti, Pd, Cu, or Al, Cu, Au.

32. A method for manufacturing a micro-electro-mechanical system (MEMS) probe card, the method comprising:
forming a first conductive pad on a surface of a substrate;
forming a resistor on the surfaces of the substrate and the first conductive pad; and
forming a second conductive pad on the surfaces of the substrate and the resistor.

33. A micro-electro-mechanical system (MEMS) probe card comprising:
a first conductive pad formed on a surface of a substrate;
a resistor formed on the surfaces of the substrate and the first conductive pad; and
a second conductive pad formed on the surfaces of the substrate and the resistor.
